(19) United States
(12) Patent Application Publication
(10) Pub. No.: US 2011/0240222 A1
(43) Pub. Date: Oct. 6, 2011

(54) PLASMA PROCESSING APPARATUS

(75) Inventors: Ikuo Sawada, Yamanashi (JP); Songyun Kang, Yamanashi (JP); Shigeru Kasai, Yamanashi (JP)

(73) Assignee: TOKYO ELECTRON LIMITED, Tokyo (JP)

(21) Appl. No.: 13/129,541

(22) PCT Filed: Nov. 17, 2009
(86) PCT No.: PCT/JP2009/069492

§ 371 Date: Jun. 17, 2011

(30) Foreign Application Priority Data
Nov. 18, 2008 (JP) 2008-294871

(51) Int. Cl. C23F 1/08; C23C 16/455; C23C 16/50; C23C 16/52

(52) U.S. Cl. 156/345.28; 156/345.34; 118/723 E; 118/696

(57) ABSTRACT

A gas shower head having many gas discharging ports formed on the lower surface is provided on the top wall of a processing container such that the gas shower head faces a placing table on which a substrate is to be placed, and the top wall of the processing container at the periphery of the gas shower head is composed of a dielectric material. A coil is provided on the dielectric material, and the phase of high frequency waves to be supplied to the gas shower head and the coil is adjusted so that the phase of the electrical field in a processing region above the substrate and the phase of the electrical field in the peripheral region surrounding the processing region are same or opposite to each other.

### TECHNICAL FIELD

The present invention relates to a plasma processing apparatus for performing plasma processing of a substrate.

### BACKGROUND ART

In a manufacturing process of a semiconductor device or a liquid crystal display (LCD), there is a process to perform a plasma processing such as an etching processing or a film forming processing of a substrate such as a semiconductor wafer (hereinafter, referred to as a wafer) or a glass plate for an LCD (hereinafter, referred to as an LCD substrate). In the case of performing the etching processing, for example, a mask pattern is formed on the surface of the substrate and the processing of lower layers (for example, in the case of the wafer, a lamination layer in which layers having different compositions, such as an anti-reflective layer, an amorphous carbon layer, a silicon oxide layer, and an etching stopping layer, are laminated in sequence from an upper side) is performed through the mask pattern. Further, when the lamination layer constituted by the multiple layers is etched, etching gas is switched for each layer and processing conditions such as a flow rate or pressure of the etching gas are adjusted. Therefore, in order to uniformly etch each layer in a plane, processing gas needs to be supplied in such a way that the concentration distribution in a processing region above the wafer is uniform in the plane, and the processing gas needs to become plasma uniformly, according to the processing condition for each layer.

As an apparatus that performs a plasma processing by making the processing gas into plasma, a parallel flat type plasma processing apparatus has been known. This apparatus places the wafer at a placing table in a processing container, supplies the processing gas toward the wafer at a lower side from a metallic gas shower head with a plurality of gas ejection holes formed on the bottom thereof, and supplies high-frequency power between the placing table and the gas shower head to make the processing gas into plasma. In this apparatus, since the gas shower head is used as described above, the processing gas can be uniformly supplied to the wafer. However, since the current path that flows between the placing table and the gas shower head becomes complicated, for example, the plasma distribution in a diameter direction of the wafer may become easily non-uniform according to the processing condition.

Further, as the plasma processing apparatus, an apparatus using an inductively coupled plasma (ICP) type has been also known. In this apparatus, the top wall of the processing container is composed of a dielectric material, for example, quartz, and a coil wound in a concentric circle shape at several times or wound in a volution type with respect to the wafer disposed on the placing table is installed on a ceiling wall. Then, an electric field is formed along the circumferential direction of the wafer in the processing container by supplying a high-frequency voltage to the coil, thereby making the processing gas into plasma. As a result, this apparatus can easily adjust an electric intensity distribution (a concentration distribution of plasma) by changing the winding position of the coil. However, since this apparatus utilizes the ceiling wall composed of the dielectric material, a gas shower head cannot be installed in this apparatus. That is, since the dielectric material is difficult to be processed, it is actually difficult to form the gas shower head by the dielectric material. And, when the metallic gas shower head is installed on the ceiling wall, the electric field of the coil is interrupted by the gas shower head. Therefore, in this apparatus, gas ejection holes are provided on the ceiling wall, for example, at the center of the processing container and the processing gas is supplied through the gas ejection holes, and as a result, the distribution of the processing gas may become easily non-uniform.

Accordingly, for example, as disclosed in of Japanese Patent Application Laid-Open No. 1997-074089 (see FIG. 3 of the publication), a technology has been known in which an upper condenser electrode is installed to face the wafer disposed on a lower condenser electrode, the ceiling wall around the upper condenser electrode is composed of the dielectric material, and an inductive coil wound in the circumferential direction is installed on the dielectric material. In this technology, the processing gas can be made into plasma by the high-frequency current supplied between the lower condenser electrode and the upper condenser electrode at the central region of the wafer, and the processing gas can be made into plasma by the electric field of the inductive coil at a circumferential margin of the wafer. Therefore, for example, a plurality of gas ejection holes are formed on the bottom of the upper condenser electrode and the processing gas is supplied from the upper condenser electrode, such that the concentration distribution of the processing gas can be uniform over the plane and the concentration distribution of plasma can be adjusted in a diameter direction of the wafer.

However, a method for making the concentration distribution of plasma even more uniform is required. For example, as an opening diameter of the mask pattern described above decreases, in-plane processing uniformity becomes significant, and as a result, as the wiring structure becomes miniaturized, a technology for making plasma more uniform has been needed. Further, instead of the present wafer having a size of 300 mm (12 inches), a large-sized wafer of 450 mm (18 inches) may be adopted, and further, the LCD substrate may become larger and larger. When a large size plasma is formed in accordance with the large substrate, plasma needs to be formed more uniformly. Further, in the large-diameter wafer as described above, since there is a concern about a deviation in plasma processing in the circumferential direction, there is a possibility that a technology will be required to make the circumferential-direction distribution of plasma uniform in addition to the diameter-direction distribution of plasma. In addition, in a large-sized LCD substrate, since there is a concern about a deviation in plasma processing at the circumference rather than the center, the distribution of plasma needs to be uniform so that excellent plasma processing is performed even at the circumference.

### SUMMARY OF THE INVENTION

The present invention has been made in an effort to provide a plasma processing apparatus capable of performing a processing operation having a high in-plane uniformity at the time of performing plasma processing of a substrate.

An exemplary embodiment of the present invention provides a plasma processing apparatus including a processing container, a placing table which is a lower electrode installed in the processing container, and a gas shower head which is an upper electrode and serves as a supplying unit of processing gas. The plasma processing apparatus makes the processing gas into plasma by applying a high-frequency electric power for generating plasma between the lower electrode and the upper electrode, and performs a plasma processing of a substrate disposed on the placing table by using plasma. The apparatus including: a first high-frequency power supply connected to any one electrode of an upper electrode and a lower electrode configured to output high-frequency electric power for generating plasma; a second high-frequency power supply configured to output high-frequency electric power having the same output frequency as the first high-frequency power supply; an inductive coil disposed to surround the one electrode connected to the first high-frequency power supply when viewed from the top side and configured to form a horizontal-direction electric field along a line connecting a side wall of the processing container and an upper region of the center of the substrate in the processing container by the high-frequency electric power supplied from the second high-frequency power supply; and a phase difference adjusting means for adjusting a phase difference between the high frequencies outputted from the first high-frequency power supply and the second high-frequency power supply in order to adjust the strength of a combined electric field of a horizontal-direction electric field generated around the one electrode in the processing container by supplying the high-frequency electric power from the first high-frequency power supply and the horizontal-direction electric field formed by the inductive coil.

An adjusting operation of adjusting the strength of the combined electric field may preferably be an operation that sets phases of the horizontal-direction electric field formed by the first high-frequency power supply and the horizontal-direction electric field formed by the second high-frequency power supply to the same phase or a reverse phase. A plurality of inductive coils are disposed in a circumferential direction of the processing container and the lengths of each conductive passage connecting each of the plurality of inductive coils and the second high-frequency power supply may preferably have the same length. Further, the plasma processing apparatus may preferably include a negative voltage supplying means connected to the gas shower head to push the electric field inducted by the inductive coils to the center of the processing container. The phase difference adjusting means may preferably include a control unit outputting a control signal for adjusting the phase difference between the horizontal-direction electric field formed by the first high-frequency power supply and the horizontal-direction electric field formed by the second high-frequency power supply.

The control unit may preferably have a function to selectively output a control signal for adjusting the horizontal-direction electric field formed by the first high-frequency power supply and the horizontal-direction electric field formed by the second high-frequency power supply to the same phase and a control signal for adjusting the corresponding horizontal-direction electric fields to reverse phases. Further, the plasma processing apparatus may preferably include a processing recipe performed with respect to the substrate and a storage unit correspondingly storing an adjustment amount of the phase by the phase difference adjusting means, and the control unit may preferably read the adjustment amount depending on the recipe from the storage unit and outputs a control signal.

According to the exemplary embodiments of the present invention, in a parallel flat type plasma processing apparatus, inductive coils are disposed to surround an upper electrode or a lower electrode connected to a first high-frequency power supply when viewed from the top side, and a horizontal-direction electric field is formed along a line connecting a side wall of the processing container and an upper region of the center of a substrate in a processing container by supplying high-frequency electric power to the inductive coils by using a second high-frequency power supply, and a combined electric field is formed by the electric field and a horizontal-direction electric field formed around any one electrode of the upper electrode or the lower electrode by using the first high-frequency power supply. In addition, since the magnitude of the combined electric field is adjusted by adjusting the phase difference between both horizontal-direction electric fields, a control factor involved in the generation of plasma increases one more. Therefore, adjustment flexibility increases in the concentration distribution of plasma to thereby contribute to improving the uniformity in plasma processing of a substrate.

### DESCRIPTION OF DRAWINGS

FIG. 1 is a longitudinal cross-sectional view showing one example of a plasma etching processing apparatus of the present invention.

FIG. 2 is a plan view of a gas shower head of the plasma etching processing apparatus, which is viewed from the top surface.

FIG. 3 is a perspective view showing coils on the gas shower head by cutting out the gas shower head.

FIG. 4 is a schematic diagram showing a control unit of the plasma etching processing apparatus.

FIG. 5 is a pattern diagram showing a state in which etching gas is being made into plasma in the plasma etching processing apparatus.

FIG. 6 is a pattern diagram showing a state in which etching gas is being made into plasma in the plasma etching processing apparatus.

FIG. 7 is a pattern diagram showing a state in which etching gas is being made into plasma in the plasma etching processing apparatus.

FIG. 8 is a pattern diagram showing a state in which etching gas is being made into plasma in the plasma etching processing apparatus.

FIG. 9 is a pattern diagram showing a state in which etching gas is being made into plasma in the plasma etching processing apparatus.

FIG. 10 is a pattern diagram showing a state in which etching gas is being made into plasma in the plasma etching processing apparatus.

FIG. 11 is a longitudinal cross-sectional view showing another example of the plasma etching processing apparatus.

FIG. 12 is a pattern diagram showing coils of a gas shower head showing another example of the coils.

FIG. 13 is a perspective view showing the coils.

FIG. 14 is a pattern diagram showing coils of a gas shower head showing another example of the coils.

FIG. 15 is a plan view of a gas shower head showing another example of the coils.

FIG. 16 is a schematic diagram showing one example of a control unit in another example described above.

FIG. 17 is a longitudinal cross-sectional view showing another example of the plasma etching processing apparatus.

FIG. 18 is a pattern diagram showing a state in which etching gas is being made into plasma in another example described above.

FIG. 19 is a schematic diagram showing one example of a control unit in another example described above.

FIG. 20 is a plan view of a gas shower head showing another example of the coils.

FIG. 21 is a characteristic diagram showing a result acquired by an exemplary embodiment of the present invention.

FIG. 22 is a characteristic diagram showing a result acquired by an exemplary embodiment of the present invention.

FIG. 23 is a characteristic diagram showing a result acquired by an exemplary embodiment of the present invention.

FIG. 24 is a characteristic diagram showing a result acquired by an exemplary embodiment of the present invention.

FIG. 25 is a characteristic diagram showing a result acquired by an exemplary embodiment of the present invention.

FIG. 26 is a characteristic diagram showing a result acquired by an exemplary embodiment of the present invention.

### EXEMPLARY EMBODIMENTS

### First Exemplary Embodiment

### Rectangular Coil, Common Power Supply

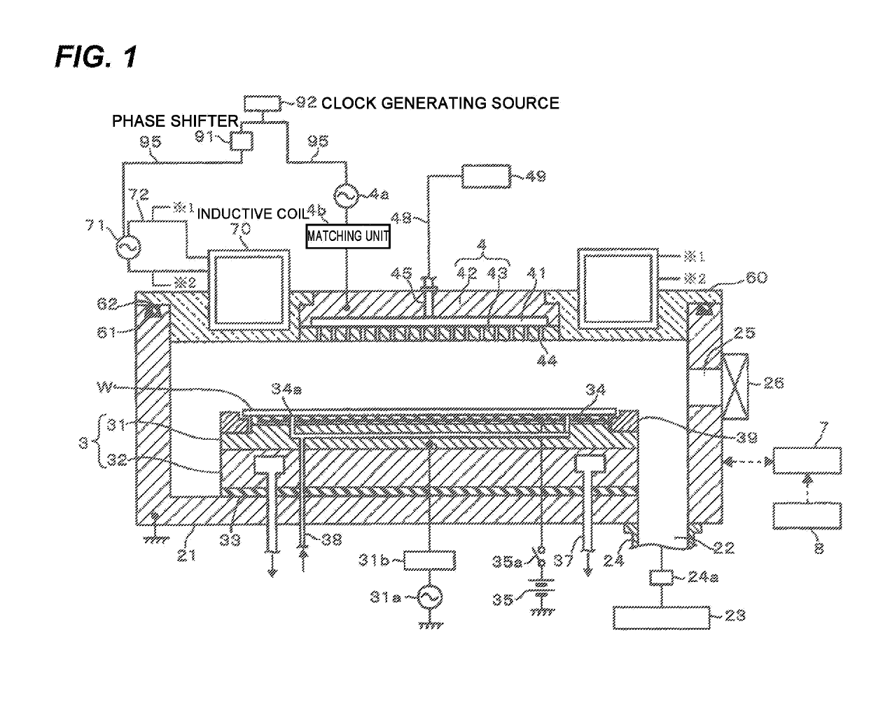

The first exemplary embodiment in which a plasma processing apparatus of the present invention is applied to a plasma etching apparatus will be described with reference to FIGS. 1 to 4. The plasma etching processing apparatus includes a processing container 21 constituted by a vacuum chamber and a placing table 3 disposed at the center of the bottom surface of processing container 21. Processing container 21 is electrically grounded and further, an exhaust port 22 is formed at a side position of placing table 3 on the bottom surface of processing container 21. A vacuum exhaust means 23 including a vacuum pump, and the like, is connected to exhaust port 22 through an exhaust pipe 24 having a pressure regulating valve 24a which is a pressure regulating means. A transfer port 25 for carrying in and out a wafer W is provided on a side wall of processing container 21, and transfer port 25 is configured to be able to open and close by a gate valve 26.

Placing table 3 is constituted by a lower electrode 31 and a support 32 supporting lower electrode 31 on a lower side thereof and disposed on the bottom surface of processing container 21 with an insulating member 33 interposed therebetween. An electrostatic chuck 34 is installed on the top of placing table 3 and voltage is applied to electrostatic chuck 34 from a high-voltage dc power supply 35 through a switch 35a, and as a result, wafer W is electrostatically adsorbed on placing table 3. A temperature control passage 37 through which temperature control media flows is formed in placing table 3, and the temperature of wafer W is controlled by the temperature control media. Further, a gas passage 38 for supplying thermoconductive gas to a rear surface of wafer W as backside gas is formed in placing table 3, and gas passage 38 is in communication with openings provided at a plurality of locations of on the top of placing table 3. A plurality of through-holes 34a that are in communication with gas passage 38 are formed in electrostatic chuck 34 described above, and the backside gas is supplied to the rear surface of wafer W through through-holes 34a.

For example, a high-frequency power supply 31a for a bias having a frequency of 13.56 MHz and electric power of 0 to 4000 W is connected to lower electrode 31 through a matching unit 31b. A high-frequency bias supplied from high-frequency power supply 31a is used to attract ions in plasma to wafer W as described below. Further, the frequency of a high frequency wave supplied to lower electrode 31 may be the same as the frequency of a high frequency wave supplied to a gas shower head 4 to be described below. Instead, the plasma processing apparatus may be configured as so called a single frequency excitation type of plasma etching apparatus in which high-frequency electric power is applied to only the upper electrode without installing high-frequency power supply 31a. A focus ring 39 is disposed on an outer periphery of lower electrode 31 to surround electrostatic chuck 34, and plasma is converged on wafer W on placing table 3 through focus ring 39.

Further, gas shower head 4 serving as the upper electrode and a supplying unit of the processing gas is disposed on the ceiling wall of processing container 21 to face placing table 3. Gas shower head 4 is constituted by an electrode part 42 having a circular concave portion on the bottom thereof, and for example, made of a conductive member such as aluminum, and the like, and a support member 43 configuring a disk-type shower plate made of a conductive member, for example, polycrystalline silicon, which is installed to cover the bottom of electrode part 42. The conductive member may be a semiconductor as described in this example, but may be a conductor (a good conductor), such as, for example, metal. A space partitioned by electrode part 42 and support member 43 forms a gas diffusion space 41 where the processing gas is diffused. Further, a region between wafer W on placing table 3 and gas shower head 4 form a processing region. For example, a first high-frequency power supply 4a having an output frequency of 40 MHz and electric power of 500 to 3000 W for forming an electric field for generating plasma in the processing region is connected to gas shower head 4 through a matching unit 4b.

A processing gas supplying path 45 that is in communication with gas diffusion space 41 is formed at the center of electrode part 42. A processing gas supplying system 49 is connected to an upstream side of processing gas supplying path 45 through a gas supplying pipe 48. Processing gas supplying system 49 is used to supply the processing gas to wafer W, and in this example, etching gas for etching processing, such as, for example, fluorocarbon gas, chlorine (Cl₂) gas, carbon monoxide (CO) gas, hydrogen bromide (HBr) gas, ozone (O₃) gas, or the like is configured to be supplied into processing container 21 together with dilution gas such as argon (Ar) gas, or the like. Further, processing gas supplying system 49 includes, for example, a plurality of branch passages on which a valve or a flow regulating unit is installed, and a gas source connected to each of the branch passages and retaining the etching gas or dilution gas described above (not shown). Processing gas supplying system 49 is configured to supply predetermined etching gas or Ar gas at a desired flow ratio according to the type of an etched layer subjected to an etching processing.

Support member 43 is airtightly compressed on electrode part 42 through a sealing member (not shown) installed at a circumferential margin of the top thereof. Further, a plurality of gas ejection holes 44 are arranged in support member 43 to supply gas to wafer W from gas diffusion space 41 with a high in-plane uniformity. A temperature control fluid passing channel (not shown) is formed in gas shower head 4, and the temperature of gas shower head 4 is configured to be controlled by the temperature control fluid that flows the temperature control fluid passing channel.

In the ceiling wall part of processing container 21, a ring-type region surrounding gas shower head 4 described above configures an outer top plate 60 and is made of a dielectric material, for example, quartz, or the like. Outer top plate 60 and gas shower head 4 are airtightly compressed through, for example, the sealing member (not shown) formed on an inner peripheral end of outer top plate 60 in a ring type. Outer top plate 60 and gas shower head 4 are fixed so that the heights of the bottoms of both sides are equal to each other. Outer top plate 60 is supported by the side wall of processing container 21 on an outer peripheral end thereof. The bottom of an outer peripheral end of outer top plate 60 is higher than the bottom of an inner periphery of outer top plate 60, and as a result, the ceiling wall (gas shower head 4 and outer top plate 60) of processing container 21 enters into the inside of processing container 21, such that gas shower head 4 and placing table 3 are close to each other. Further, a ring-type groove 61 is formed on a top surface of the side wall of processing container 21 throughout a peripheral direction and, for example, a sealing member 62 such as an O-ring or the like is received in groove 61. In addition, when, for example, an atmosphere in processing container 21 is in a vacuum state by vacuum exhaust means 23 described above, outer top plate 60 is pulled to processing container 21, such that an inner space of processing container 21 is airtightly sealed through sealing member 62.

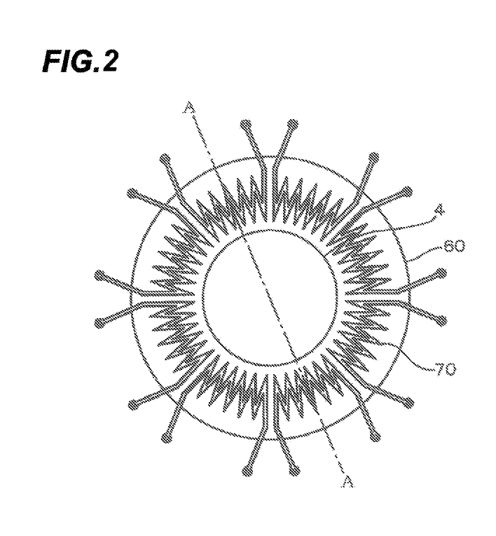

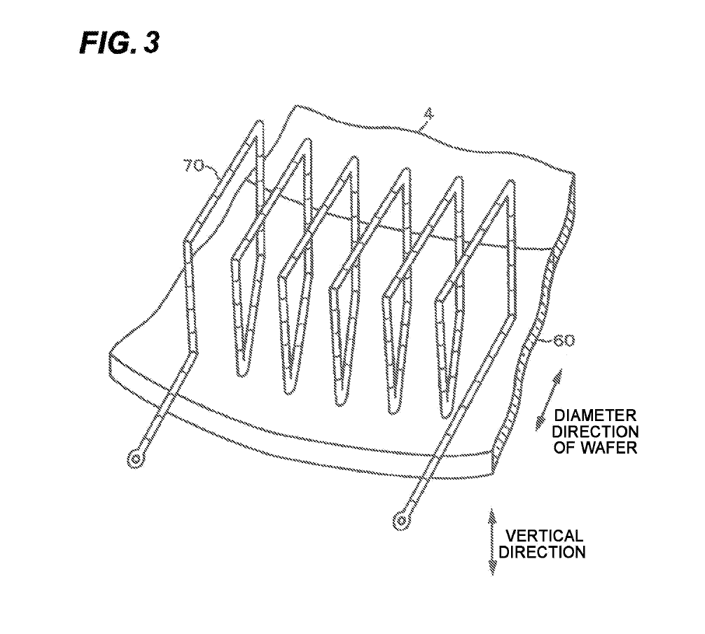

Inductive coil 70 which is an inductive conductor in which a wire made of, for example, metal is wound at several times is installed at a plurality of locations, for example, eight (8) locations on outer top plate 60 at regular intervals in a circumferential direction, as shown in FIGS. 2 and 3. As seen from the top side, an axial line of each inductive coil 70 approximately coincides with a circular arc along an outer margin of wafer W. Further, each inductive coil 70 has a rectangular cross section, and a top surface and a bottom surface thereof are parallel to the surface of wafer W on placing table 3. Further, as shown in FIG. 1, a lower side of inductive coil 70 is actually installed to enter into the inside of outer top plate 60, but in FIGS. 2 and 3, inductive coil 70 is schematically shown for simplification of the figures.

Inductive coil 70 forms a second electric field E2 that extends (has an amplitude) in a radially horizontal direction along a line connecting between the side wall of processing container 21 and an upper region of the center of wafer W throughout the circumferential direction by electro-induction with outer top plate 60 interposed therebetween in the circumferential margin region surrounding a lower region of inductive coil 70 in processing container 21, that is, a lower space (a processing region) of gas shower head 4. In order to form the second electric field E2, the plurality of inductive coils 70 are connected in parallel to, for example, a common second high-frequency power supply 71 having an output frequency of 40 MHz equivalent to the output frequency of first high-frequency power supply 4a and electric power of 200 to 1200 W through a conductive passage 72, respectively.

Further, in order to reconcile phases of second electric field E2 over the circumferential direction in which the amplitude is repeated between a direction from the center to the outer periphery and a direction from the outer periphery to the center, a plurality of lines of conductive passages 72 connecting inductive coil 70 and second high-frequency power supply 71 to each other have the same length. Further, in order to reconcile magnitudes of each of second electric fields E2 formed by each of inductive coil 70, the plurality of lines of conductive passages 72 have, for example, the same diameter so that impedances of the conductive coil 70 coincide with each other, respectively. Further, in FIG. 3, only one inductive coil 70 is enlarged and shown for convenience. In addition, although schematically shown in FIGS. 2 and 3, inductive coil 70 is wound at several times. FIG. 1 described above is a longitudinal cross-sectional view at the time of cutting a processing container 21 taken along line A-A of FIG. 2.

Herein, when the high-frequency electric power from first high-frequency power supply 4a is supplied to the upper electrode (gas shower head 4), the electric field is formed between gas shower head 4 and the lower electrode (placing table 3), but at the same time, a first electric field E1 of a horizontal direction (which oscillates in the horizontal direction) is also formed between in the vicinity region of the bottom of gas shower head 4 in processing container 21 and the side wall of processing container 21. More particularly, the direction of first electric field E1 follows a line that extends radially in a diameter direction from the center of processing container 21 when viewed from the top side. In addition, in this exemplary embodiment, in order to adjust the magnitude of a combined electric field of a second electric field E2 of the horizontal-direction (a diameter-direction) formed in processing container 21 by supplying the high-frequency electric power to inductive coil 70 by using second high-frequency power supply 71 and first electric field E1, phases of electric fields E1 and E2 are adjusted. As a result, the output frequencies of first high-frequency power supply 4a and second high-frequency power supply 71 are set to the same value, such that a system is configured so as to adjust a phase difference between the high-frequency wave outputted from first high-frequency power supply 4a and the high-frequency wave outputted from second high-frequency power supply 71. One example of a method for adjusting the phase difference will be described below.

Each of first high-frequency power supply 4a and second high-frequency power supply 71 is configured to generate the high-frequency wave based on a clock inputted from outside. In addition, a clock generating source 92 is installed outside, signal lines (signal paths; 95) are distributed to first high-frequency power supply 4a and second high-frequency power supply 71 from clock generating source 92, and a phase shifter 91 is installed on any one distribution signal line 95. The phase shifter 91 adjusts the phase of a clock signal based on an analog signal or a digital signal from a controller, and as a result, the phase difference of each of the high frequencies of first high-frequency power supply 4a and second high-frequency power supply 71 is adjusted so that the phase difference between first electric field E1 and second electric field E2 becomes a desired value, for example, the same phase or a reverse phase. Further, as described above, electric fields E1 and E2 can have the same phase or the reverse phase by setting the phase difference between the high frequencies outputted from first and second high-frequency power supplies 4a and 71 to be, for example, the same phase or the reverse phase. Herein, by a simulation described below, when first electric field E1 and second electric field E2 have the same phase, plasma concentration is higher at the circumferential margin than at the center of the processing region, whereas when first electric field E1 and second electric field E2 have the reverse phase, plasma concentration is higher at the center than at the circumferential margin of the processing region.

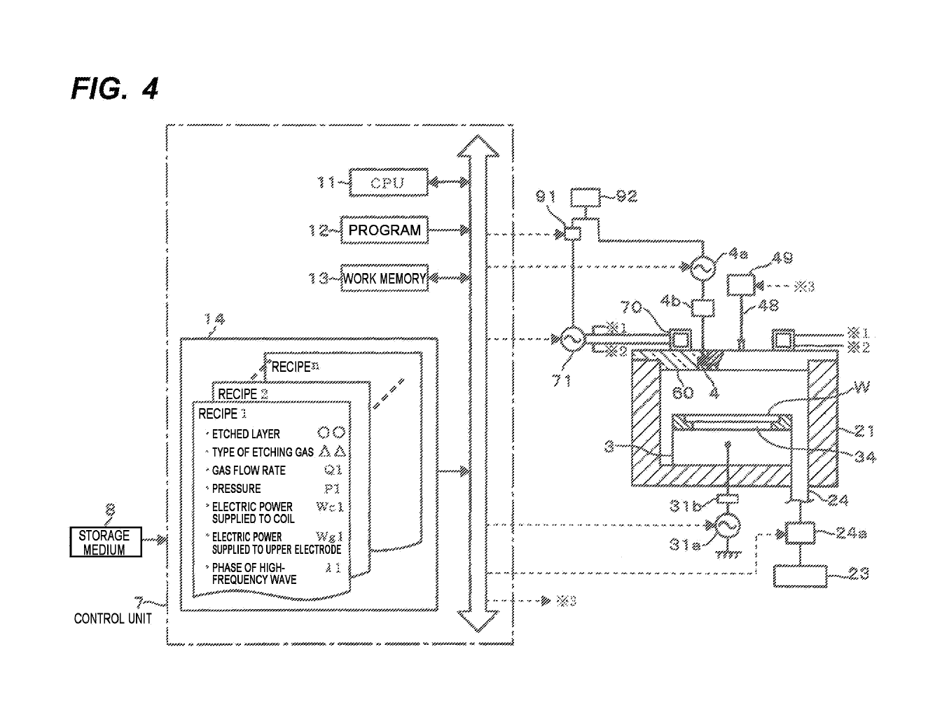

Further, as shown in FIG. 4, a control unit 7 is connected to the plasma etching processing apparatus. Control unit 7 includes a CPU 11, a program 12, a work memory 13 for an operation, and a memory 14 for a storage unit. Memory 14 is provided for each recipe with processing conditions such as a type of the layer (the etched layer) where the etching processing is performed, a type of the etching gas, a gas flow rate, a processing pressure, a magnitude of the electric power of first high-frequency power supply 4a supplied to gas shower head 4, and a magnitude of the electric power of second high-frequency power supply 71 supplied to inductive coil 70, and a region where the phase of the high-frequency wave adjusted by phase shifter 91 is recorded. As described below, since multilayers of different types are laminated on wafer W, when the etching processing is performed with respect to the mutlilayers, the type of the etching gas is different for each layer and the processing condition such as the flow rate of the etching gas or processing pressure is also different for each layer. As a result, as described in exemplary embodiments described below as well, there may be a deviation in concentration distribution of plasma in the diameter direction of wafer W according to the processing condition.

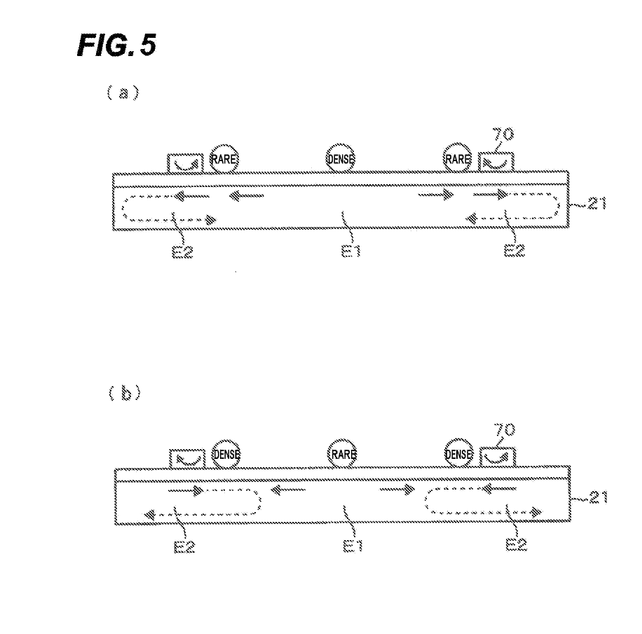

Accordingly, in the present invention, in order to uniformly perform the plasma etching processing in the plane, when there is the deviation in concentration distribution of plasma in the diameter direction of wafer W, the concentration of plasma in the diameter direction is made uniform. For example, when the concentration of plasma increases at the center, plasma is made spread to the circumferential margin, whereas when the concentration of plasma increases to the circumferential margin, plasma is pushed into the center. Specifically, the phase of the high-frequency wave (voltage) supplied to second high-frequency power supply 71 is adjusted for each layer (processing condition) by phase shifter 91 so that the phase of first electric field E1 formed in the processing region (has the amplitude) is the same as the phase of second electric field E2 at the circumferential margin as shown in FIG. 5A when the concentration of plasma increases at the center of wafer W. Whereas, the phase of first electric field E1 is reversed to the phase of second electric field E2 as shown in FIG. 5B when the concentration of plasma increases at the circumferential margin of wafer W. Further, since electric fields E1 and E2 have amplitudes in a right and left directions in FIG. 5, directions (phases) of electric fields E1 and E2 at any instant are schematically shown in FIG. 5. In addition, arrows indicated in inductive coil 70 represents directions of high frequencies which flow on corresponding inductive coil 70 when electric field E2 is formed.

Further, as a factor to adjust the magnitude of the combined electric field of first electric field E1 and second electric field E2, there is an electric power of each of the high frequencies supplied from high-frequency power supplies 4a and 71, in addition to the phase of the high-frequency wave adjusted by phase shifter 91. In memory 14, for example, a proper value of the factors previously acquired by a test or calculation is stored for each recipe (for example, for each layer to be etched and for each processing condition). In program 12, a command is configured to perform the etching processing by reading the aforementioned recipe in work memory 13 for an operation from memory 14 through CPU 11 for each layer to be etched, and sending a control signal to each component of the plasma etching processing apparatus according to this recipe to perform each step to be described below. Program (including a program related to an inputting operation or a display of processing parameters) 12 is stored in, for example, storage medium 8 such as a hard disk, a compact disk, a magneto-optical disk, a memory card, and the like and installed in control unit 7 by storage medium 8.

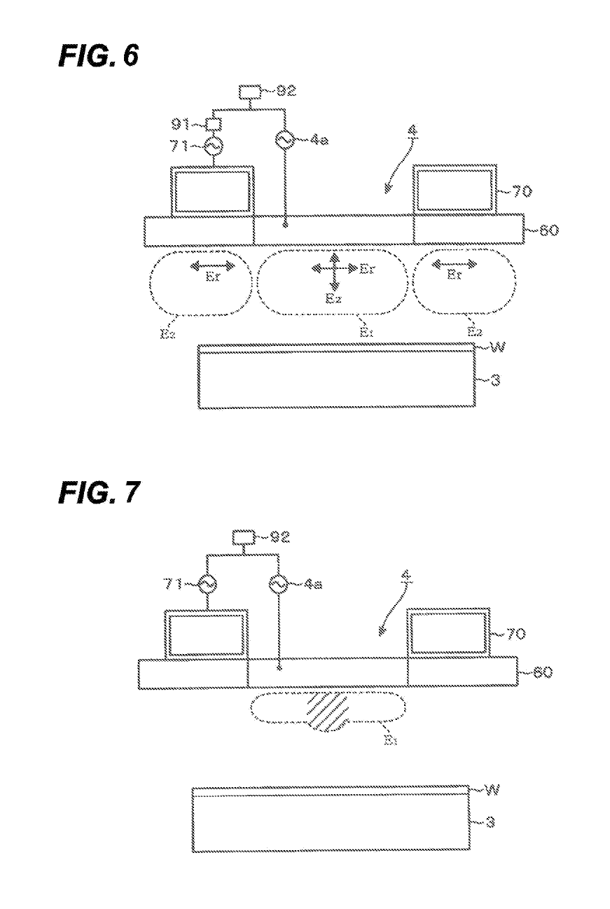

Next, an operation of the plasma etching processing apparatus will be described with reference to FIGS. 6 to 10. Herein, a semiconductor wafer (hereinafter, referred to as ‘a wafer’) W which is a processed substrate is simply described. Wafer W is configured by laminating lamination layers including, for example, a photoresist mask in which a predetermined pattern is patterned, for example, an anti-reflective layer made of an organic material, an amorphous carbon layer, an insulating layer (an SiO₂ layer or an SiCOH layer) or a poly-Si (polycrystalline silicon) layer, and for example, an etching stop layer made of an inorganic layer in sequence on a silicon layer from the top side.

First, the recipe is read in work memory 13 from memory 14 according to the corresponding layer to be etched formed on the surface of wafer W. In this example, since the to-be-etched layer of an outer layer is, for example, the anti-reflective layer, the corresponding recipe is read in advance. In addition, by a substrate transferring means (all not shown), wafer W is carried into processing container 21 from a vacuum transfer chamber maintained in a vacuum atmosphere, disposed, adsorbed, and held on placing table 3, and thereafter, gate valve 26 is closed. Continuously, an inner part of processing container 21 is made in a vacuum state by completely opening, for example, pressure regulating valve 24a by vacuum exhaust means 23, and wafer W is adjusted to a predetermined temperature by supplying the temperature control media, and the backside gas of which the temperatures are controlled to a predetermined temperature from temperature control passage 37 and gas passage 38.

Meanwhile, control unit 7 reads the recipe and thereafter, outputs the control signal to a controller (not shown), and as a result, the controller controls phase shifter 91 so that the phase of the control signal reaches a phase shift amount stored in the recipe. In addition, as a phase difference according to the adjusted phase shift amount, for example, high-frequency electric power of 40 MHz is outputted from first high-frequency power supply 4a and second high-frequency power supply 71, respectively. As a result, although the high-frequency electric field is formed between gas shower head 4 and placing table 3, horizontal (diameter)-direction first electric field E1 is also generated as described above. Further, the high-frequency electric power is supplied to inductive coil 70, such that second electric field E2 that oscillates along the line extending in the horizontal (diameter) direction, schematically, radially is formed at the circumferential margin region of processing container 21. In addition, a high-frequency wave for bias having, for example, a frequency of 13.56 MHz and electric power of, for example, 500 W is supplied to placing table 3 from high-frequency power supply 31a.

In addition, when the pressure in processing container 21 is adjusted to a predetermined pressure by supplying, for example, processing gas composed of etching gas and Ar gas into processing container 21 from processing gas supplying system 49, the processing gas is diffused into processing container 21 and made into plasma by the high-frequency electric power supplied between gas shower head 4 and placing table 3. Further, in the processing gas, the combined electric field of first electric field E1 and second electric field E2, that is, first electric field E1 of which the magnitude is adjusted by second electric field E2 contributes to the generation of plasma.

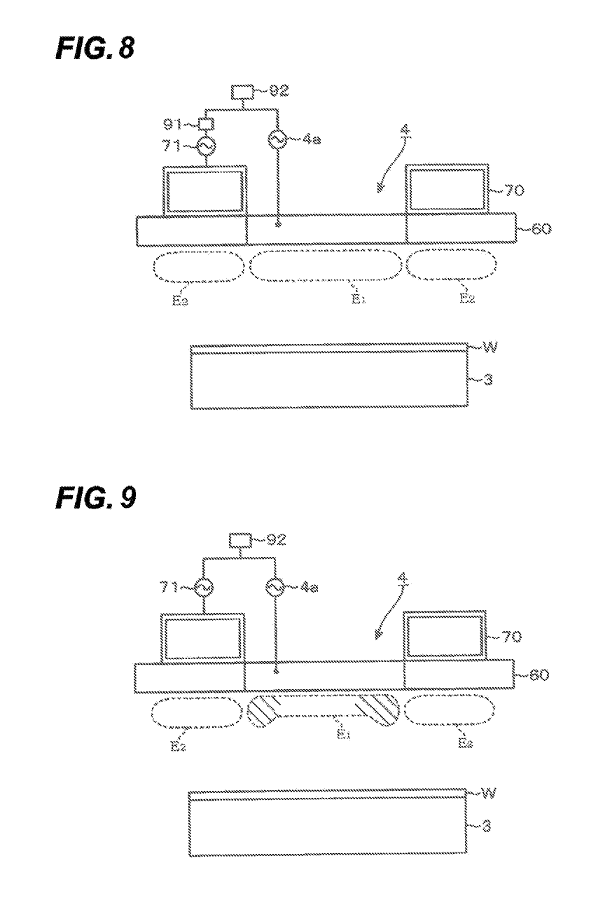

Herein, for example, when the concentration of plasma in the processing region at the time of supplying the high-frequency wave to second high-frequency power supply 71 without adjusting the phase by using phase shifter 91 is higher at the center than at the circumferential margin as shown in FIG. 7, phase shifter 91 adjusts the phase so that electric fields E1 and E2 have the same phase as shown in FIG. 5A. As a result, the combined electric field spread to the circumferential margin is formed, that is, apparent electric field E1 is spread to the circumferential margin, such that the concentration of plasma becomes uniform throughout the processing region. Further, since electric field E2 is formed at the circumferential margin region and the strength of each of electric fields E1 and E2 is adjusted by appropriately adjusting each of the high-frequency electric powers supplied from high-frequency power supplies 4a and 71, as described above, electric field E1 spread outwards and electric field E2 overlap each other, and as a result, uniform plasma is formed in the plane as shown in FIG. 8.

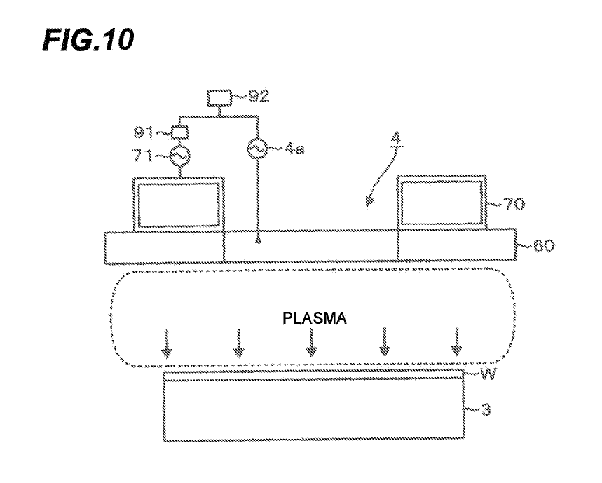

Meanwhile, when the concentration of plasma at the time of supplying the high-frequency wave to second high-frequency power supply 71 without adjusting the phase is higher at the circumferential margin than at the center as shown in FIG. 9, phase shifter 91 adjusts the phase so that electric fields E1 and E2 have the reverse phase as shown in FIG. 5B. Similarly in this case, the concentration of plasma becomes uniform throughout the processing region and the strengths of electric fields E1 and E2 are appropriately adjusted, and as a result, plasma is formed in the plane with a uniform concentration. Further, in FIGS. 7 and 9, portions where the concentration of plasma increases are marked with oblique lines. In addition, when plasma is in contact with the processing gas, the processing gas is made into plasma, such that plasma is generated successively. Since ions in plasma generated as above are attracted to placing table 3 by the high-frequency wave used for bias as shown in FIG. 10, etching processing having high verticality is performed. In addition, the anti-reflective layer is etched until the amorphous carbon layer below the anti-reflective layer is exposed.

Thereafter, supplying the processing gas stops, and supplying the high-frequency wave to inductive coil 70 and gas shower head 4 stops. In addition, the inner part of processing container 21 is vacuum-exhausted, and continuously, a recipe for the amorphous carbon layer to be etched is read from memory 14 to etch the amorphous carbon layer. Thereafter, recipes for layers below the amorphous carbon layer are also read in sequence to etch the corresponding layers.

According to the exemplary embodiments, when viewed from the top side, inductive coil 70 is disposed to surround gas shower head 4 connected to first high-frequency power supply 4a, and the high-frequency electric power is supplied to inductive coil 70 by second high-frequency power supply 71, such that horizontal-direction electric field E2 is formed in processing container 21 along the line connecting the side wall of processing container 21 and an upper region of the center of wafer W. The combined electric field is then formed by horizontal (diameter)-direction electric field E1 formed around gas shower head 4 by electric field E2 and first high-frequency power supply 4a. In addition, since the magnitude of the combined electric field is adjusted by adjusting the phase difference between both horizontal-direction electric fields E1 and E2, a control factor involved in the generation of plasma increase one more. Therefore, an adjustment flexibility increases in the density distribution of plasma to thereby contribute to improving uniformity in plasma processing of wafer W.

Thus, since electric field E1 can be pushed into the center or spread to the circumferential margin, the concentration distribution of plasma in the diameter direction can be made uniform according to a processing recipe. Accordingly, since the concentration of plasma can be made uniform over the plane, plasma processing having a high in-plane uniformity which is an etching processing in this exemplary embodiment can be performed with respect to wafer W. Further, since the concentration of plasma in the processing region can be adjusted by merely adjusting the phase of the high-frequency wave supplied to second high-frequency power supply 71, the concentration of plasma can be easily adjusted according to etched layers (recipe). Further, an amount of plasma spread to the circumferential margin or pushed into the center can be adjusted by adjusting each of the electric powers of the high-frequencies supplied into processing container 21 from the high-frequency power supplies 4a and 71, respectively, and since the concentrations of plasma in the processing region and the circumferential margin region can be uniform, the concentration of plasma in the plane can be made uniform even further.

Further, as described above, impedances between second high-frequency power supply 71 and each of the plurality of inductive coils 70 has the same value and each conductive passage 72 has the same length at the time of adjusting the phase of the high-frequency wave supplied to inductive coil 70, and as a result, the phase of the high-frequency wave and the magnitude of electric field E2 supplied to inductive coil 70 can be adjusted to be the same in the circumferential direction. Further, in the above example, each inductive coil 70 has a circular arc shape and further, has a square shape so that the top and the bottom surfaces of each inductive coil 70 are horizontal to each other, but when horizontal (diameter)-direction electric field E2 is formed, for example, each inductive coil 70 may have a circular shape.

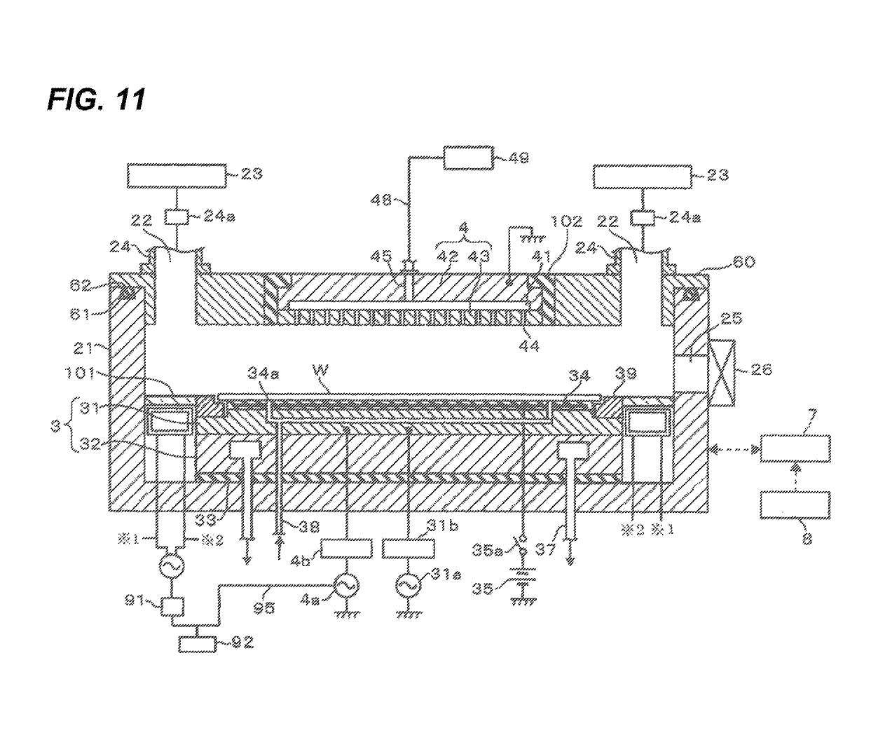

Furthermore, in the exemplary embodiment, a single frequency excitation type plasma etching processing apparatus by only the upper electrode is used by connecting first high-frequency power supply 4a to gas shower head 4, or a dual frequency excitation type plasma etching processing apparatus by both of the upper electrode and the lower electrode is used by further connecting high-frequency power supply 31a to placing table 3. However, the single frequency excitation type or dual frequency excitation type apparatus by only the lower electrode may be used by connecting first high-frequency power supply 4a to placing table 3. In this case, as shown in FIG. 11, for example, a dielectric member 101 is disposed throughout the circumferential direction around placing table 3, and inductive coil 70 is disposed below dielectric member 101. Further, in this case, exhaust port 22 is formed on the ceiling wall, for example, outer top plate 60 of processing container 21 or the side wall of processing container 21. In addition, in this case, when outer top plate 60 is configured by a conductor, a ring-type insulating member 102 may be installed between outer top plate 60 and gas shower head 4. Even in this apparatus, the plasma etching processing is performed as described in the above example, and as a result, the same effect can be acquired.

### Second Exemplary Embodiment

### Flat-Type Coil, Common Power Supply

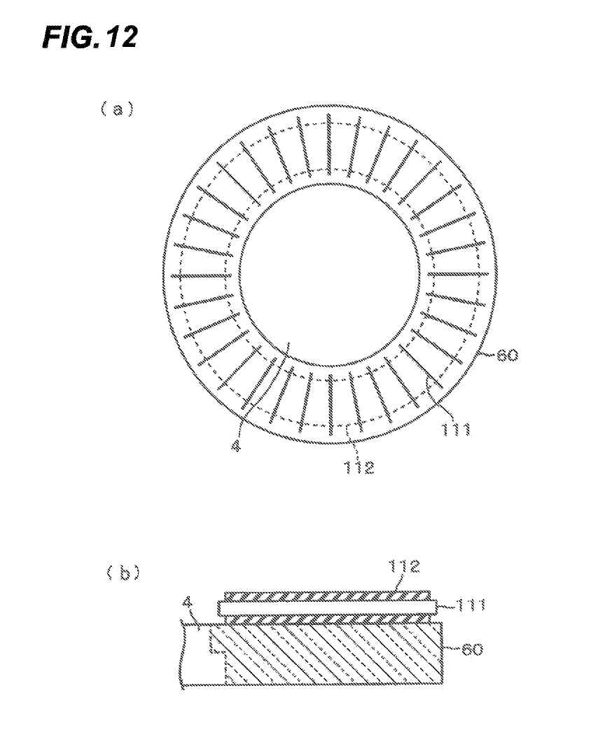

In the first exemplary embodiment, rectangular inductive coil 70 has been described, but in the second exemplary embodiment, for example, a linear wire 111 is radially disposed in a plurality of lines in the circumferential direction in order to form second electric field E2 as shown in FIG. 12. In the second exemplary embodiment, a plurality of wires 111 are buried in a ring-type flat plate 112 made of, for example, the dielectric material and flat plate 112 is installed on outer top plate 60 together with the plurality of wires 111 so that an inner peripheral end and an outer peripheral end of wire 111 are exposed, as shown in FIG. 12B.

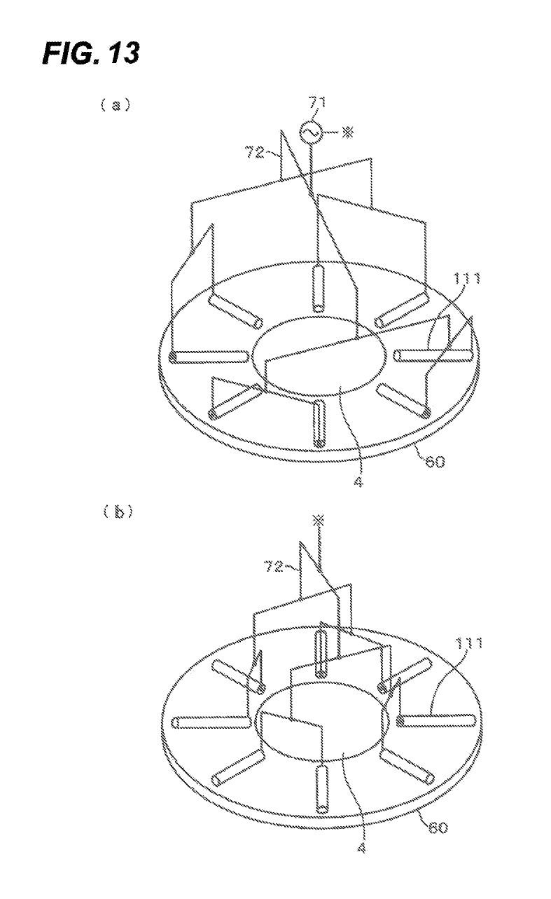

Further, in order to connect conductive passages 72 to the plurality of wires 111 so that impedances between the plurality of wires 111 and second high-frequency power supply 71 have the same value, for example, conductive passages 72 are disposed as shown in FIG. 13. Specifically, for example, second high-frequency power supply 71 is installed above gas shower head 4 and one conductive passage 72 extending from second high-frequency power supply 71 is branched into two and each of two conductive passages 72 is branched into two as well, and thus, conductive passages 72 are sequentially branched to form plural lines of conductive passages 72 having the same length, as shown in FIG. 13A. In addition, end portions of plural lines of conductive passages 72 are connected to each end, which are, for example, the outer peripheral ends of wires 111. Also, as shown in FIG. 13B, additional plurality lines of conductive passages 72 having the same length extending from second high-frequency power supply 71 are connected to the other ends, which are, for example, the inner peripheral ends of wires 111 as well, such that second high-frequency power supply 71 and each wire 111 are connected to each other by conductive passages 72 having the same length.

Furthermore, in FIG. 12A described above, wires 111 are schematically shown in a linear type, and the number of wires 111 shown in FIG. 13 is smaller than the actual number of wires 111. In addition, in FIG. 13, flat plate 112 is not shown. Further, conductive passages 72 are actually connected to both ends of all wires 111, but since the figure becomes complicated, conductive passages 72 are shown dividually in FIGS. 13A and 13B. Even in the second exemplary embodiment, the plasma etching processing is performed similarly, and as a result, the same effect can be acquired. Further, since each impedance of wires 111 decreases as compared with the case of mounting rectangular inductive coil 70, plasma can be generated efficiently. Even in this case, wires 111 may be installed below processing container 21 as described in FIG. 11.

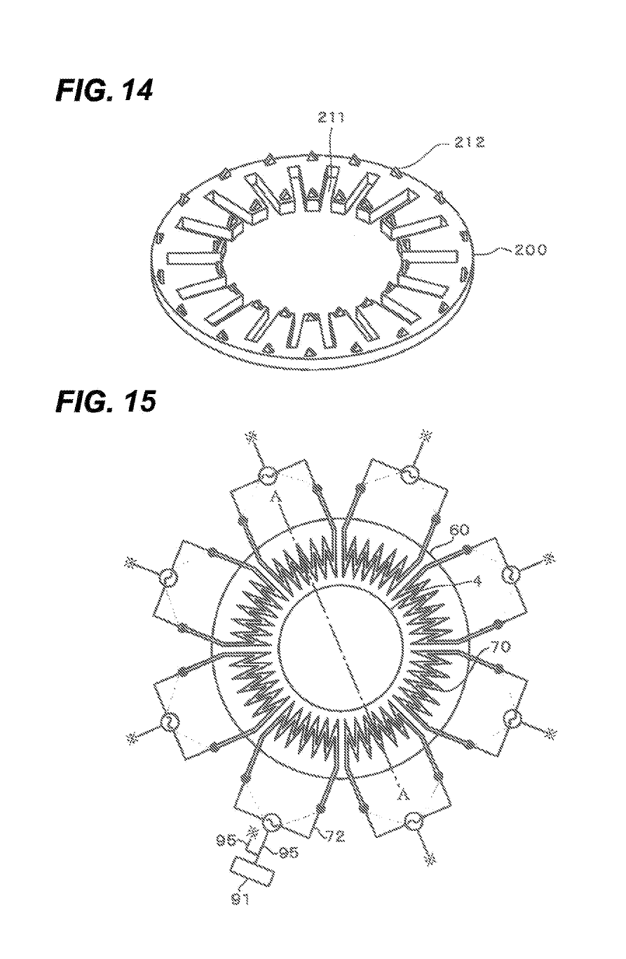

Further, in order to form second electric field E2, for example, a ring body 200 made of metal such as aluminum (Al) or copper (Cu) may be installed on outer top plate 60 as shown in FIG. 14. In FIG. 14, reference numeral 211 represents slits formed at a plurality of locations toward a diameter direction (outer peripheral side) from an inner peripheral side of ring body 200, and reference numeral 212 represents a plurality of contacts for supplying current between the inner peripheral side and the outer peripheral side of ring body 200. By supplying high-frequency current between contacts 212 and 212, radial electric field E2 is formed in the diameter direction similar to wires 111 described above.

### Third Exemplary Embodiment

### Rectangular Coil, Plural Power Supplies

In the first exemplary embodiment, the high-frequency wave is supplied to the plurality of inductive coils 70 from common second high-frequency power supply 71. However, in the third exemplary embodiment, for example, second high-frequency power supply 71 is connected to each inductive coil 70 as shown in FIG. 15. Even in this case, each conductive passage 72 has the same length so that the impedances between second high-frequency power supply 71 and each inductive coil 70 have the same value. Further, common phase shifter 91 is connected to plural second high-frequency supplies 71, and thus, signal passages 95 have the same length so that impedances between phase shifter 91 and plural second high-frequency power supplies 71 have the same value.

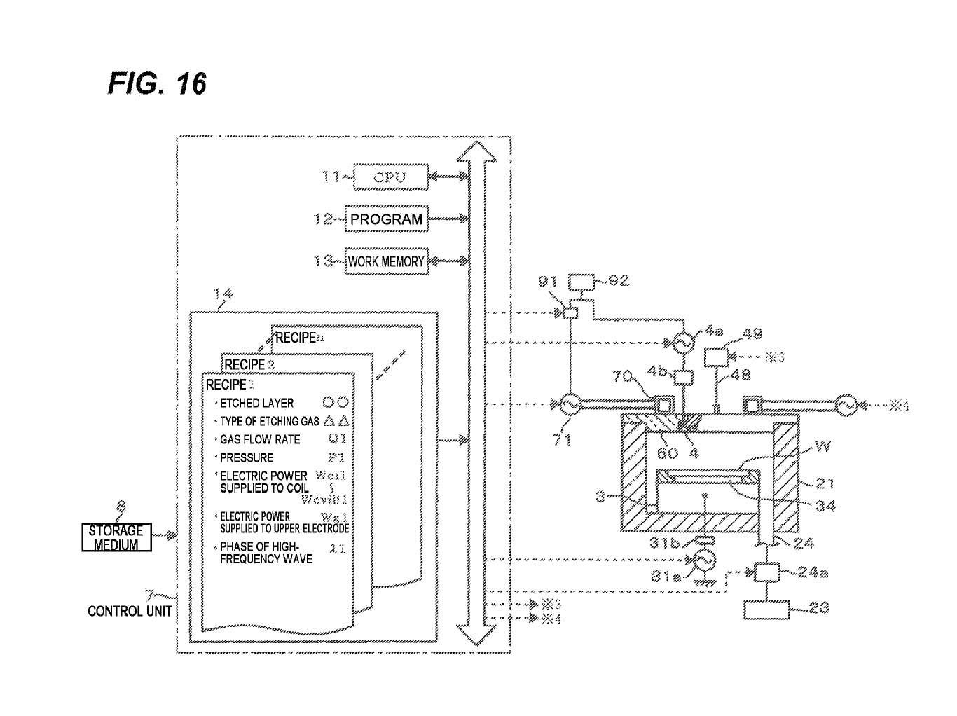

In this apparatus, the plasma etching processing may be performed similarly as each example described above. However, the apparatus may be configured such that the concentration distribution of plasma in the circumferential direction of wafer W may be uniform in addition to the concentration distribution of plasma in the diameter direction of wafer W. In this case, specifically, a region storing each magnitude of the high-frequency electric powers supplied to each inductive coil 70 is provided, as shown in FIG. 16, in memory 14 of control unit 7 described above for each recipe so that the concentration of plasma in the circumferential direction of wafer W can be uniform in addition to the processing conditions, the high frequency electric power supplied from high-frequency power supply 4a, or the phase of the high-frequency wave adjusted by phase shifter 91. Even the electric power of the high-frequency wave supplied to each inductive coil 70 is previously acquired by the experiment or calculation.

In addition, at the time of etching the etched layer on wafer W, the concentration of plasma in the circumferential direction becomes uniform in addition to the concentration of plasma in the diameter direction, and the etching processing having high verticality is performed in the plane. In this example, common phase shifter 91 is connected to each second high-frequency power supply 71, but additional phase shifter 91 may be installed in each second high-frequency power supply 71. Even in this example, inductive coil 70 may be installed below processing container 21 as shown in FIG. 11, and plural lines of wires 111 are installed as inductive coil 70 and plural second high-frequency power supplies 71 may be connected to plural lines of wires 111, respectively, as shown in FIGS. 12 and 13.

### Fourth Exemplary Embodiment

### Rectangular Coil, DC

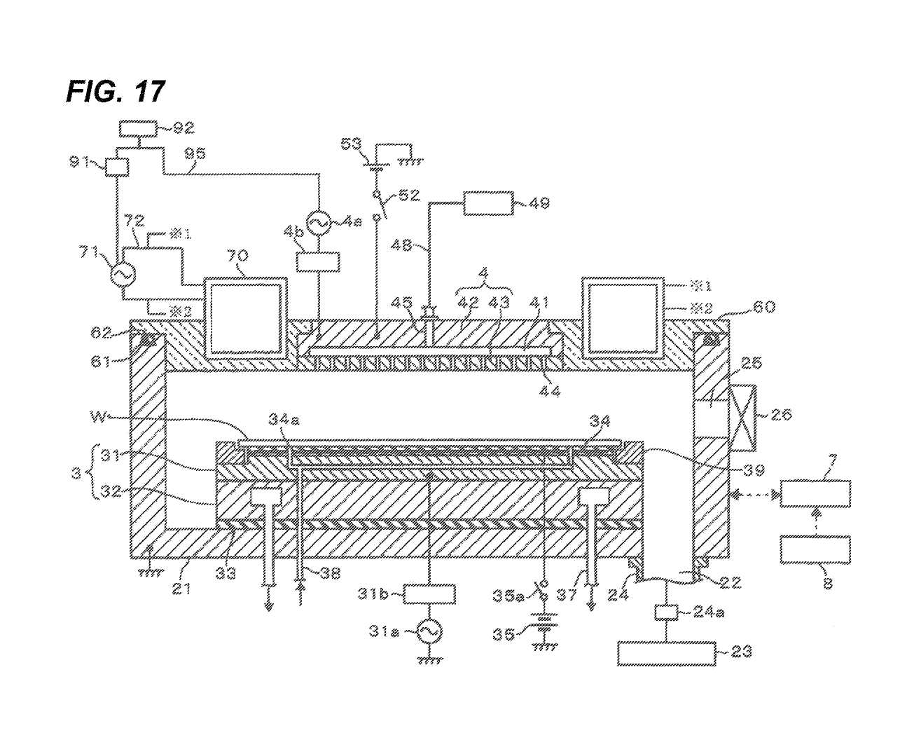

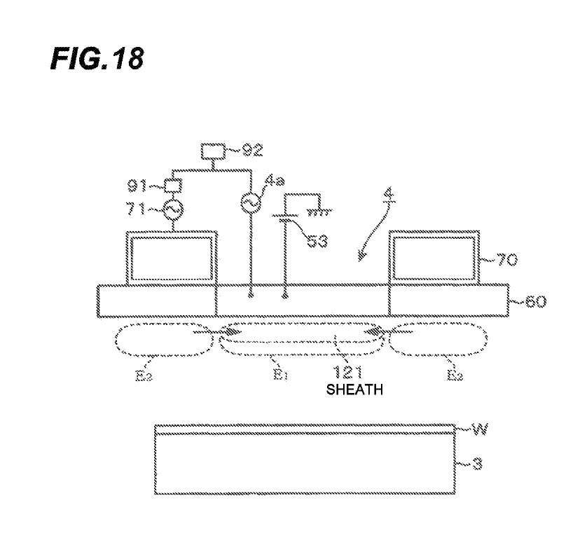

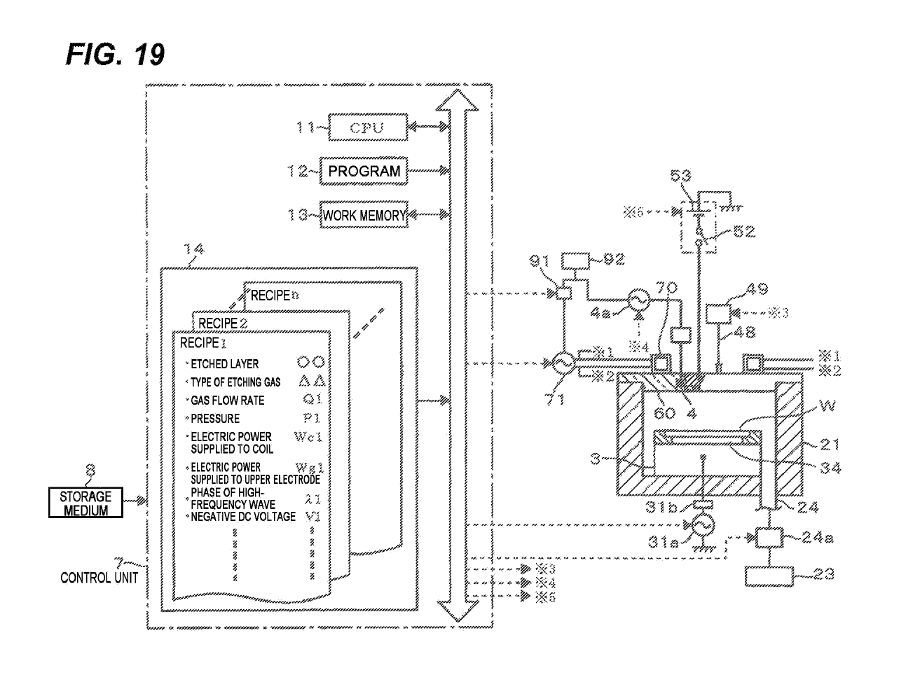

Next, the fourth exemplary embodiment of the present invention will be described. For example, a DC power supply 53 for applying negative DC voltage of 0 to −2000 V as a negative voltage supplying means is connected to electrode part 42 described above through a switch 52, as shown in FIG. 17. DC power supply 53 is used to form a sheath 121 having a thickness depending on the magnitude of voltage in a region below gas shower head 4 when plasma is generated, as shown in FIG. 18. Electric field E2 formed (induced) at the circumferential margin of the processing region by inductive coil 70 can be attracted to the center of the processing region by sheath 121. Therefore, the magnitude of the negative DC voltage applied to DC power supply 53 is stored in memory 14 described above for each recipe in addition to the processing conditions, the magnitudes of the high-frequency voltages supplied from high-frequency power supplies 4a and 71, and the phase of the high-frequency wave adjusted by phase shifter 91, as shown in FIG. 19. The magnitude of the negative DC voltage is acquired as well in advance by an experiment or a calculation.

In the exemplary embodiment, at the time of performing the etching processing, since electric field E2 attracted to the center of processing container 21 is also adjusted by sheath 121 in addition to the magnitude of the high frequency electric power supplied from each of high-frequency power supplies 4a and 71 and the phase of the high-frequency wave supplied from high-frequency power supply 71, the concentration of the electric field becomes even more uniform in the plane. As a result, the amount of plasma becomes uniform in the plane, thereby performing a uniform etching processing. Further, even in the exemplary embodiment, inductive coil 70 may be installed below processing container 21 as shown in FIG. 11, wires 111 may be disposed instead of inductive coil 70, and second high-frequency power supply 71 may be individually connected to plural inductive coil 70 or plural wires 111, as shown in FIGS. 12 and 13.

### Fifth Exemplary Embodiment

### Rectangular Substrate

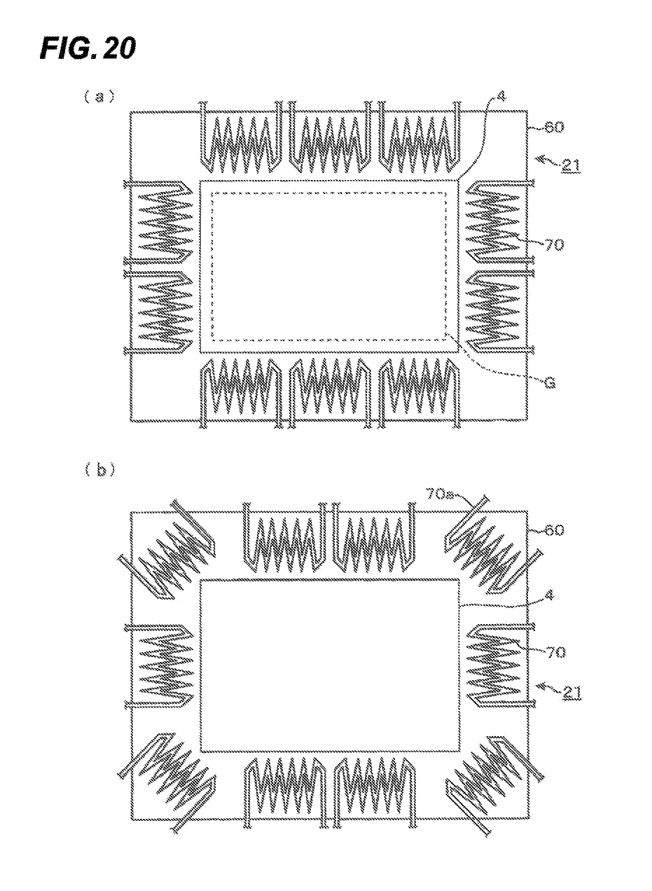

In each of the above-described exemplary embodiments, the configuration for processing circular wafer W has been described. However, as described in the fifth exemplar embodiment, the present invention may be adopted in processing a rectangular substrate, for example, a glass substrate (hereinafter, referred to as an ‘LCD substrate’) G for a liquid crystal display (LCD). Even in this case, as shown in FIG. 20A, processing container 21 and gas shower head 4 having a rectangular plane shape when viewed from the top side are used. Further, inductive coil 70 is wound on a circumference of a shaft that extends linearly along an outer margin of LCD substrate G when viewed from the top side. In the fifth exemplary embodiment, the horizontal-direction electric field is formed along the line connecting the side wall of processing container 21 and an upper region of the center of LCD substrate G when viewed from the top side. Further, herein, the “line” represents an extending line horizontally perpendicular to any one side of horizontal and vertical lines of LCD substrate G from the side wall of processing container 21. Even in rectangular LCD substrate G, the etching processing is uniformly performed similar to wafer W described above, and as a result, the same effect can be acquired.

In plasma processing of rectangular LCD substrate G, a deviation may occur in processing corner (edge) portions. In this case, as shown in FIG. 20B, inductive coil 70a may be disposed toward the corner portions, in addition to inductive coil 70 shown in FIG. 20A. By disposing inductive coil 70a toward the corner portions, etching processing having a higher in-plane uniformity can be performed. Further, even in a plasma processing apparatus for processing rectangular LCD substrate G, inductive coil 70 may be disposed below processing container 21, wires 111 may be installed instead of inductive coil 70, and plural second high-frequency power supplies 71 may be individually connected to plural inductive coil 70 or wires 111, or negative DC power supply 53 may be installed, as described above.

In each of the above-described exemplary embodiments, since the high-frequency wave is supplied to inductive coil 70 as well in addition to the high-frequency wave supplied to gas shower head 4 in order to form first electric field E1 for generating plasma, energy supplied into processing container 21 increases as compared with a case in which inductive coil 70 is not installed, and as a result, plasma can be easily obtained.

Further, in each exemplary embodiment, phase shifter 91 is installed between clock generating source 92 and second high-frequency power supply 71 at the time of adjusting the phase of the high-frequency. However, the phase of the high-frequency wave supplied to first high-frequency power supply 4a may be adjusted by installing phase shifter 91 between clock generating source 92 and first high-frequency power supply 4a without installing phase shifter 91 between clock generating source 92 and second high-frequency power supply 71. In this case, for example, the high-frequency electric power supplied to gas shower head 4 is shared by plural recipes, such that the concentration of plasma in the diameter direction may be adjusted by the high-frequency electric power supplied to inductive coil 70. Moreover, by installing phase shifter 91 between clock generating source 92, and first high-frequency power supply 4a and second high-frequency power supply 71, respectively, the phases of the high frequencies supplied to each of high-frequency power supplies 4a and 71 may be adjusted. Further, although the high-frequency wave is supplied to first high-frequency power supply 4a and second high-frequency power supply 71 from common clock generating source 92, separate clock generating sources 92 and 92 may be connected to first high-frequency power supply 4a and second high-frequency power supply 71, respectively. In this case, phase shifter 91 may be installed between clock generating sources 92, and first high-frequency power supply 4a and second high-frequency power supply 71, respectively Alternatively, the phase difference between the high-frequencies supplied to one high-frequency power supply 4a (71) and the other high-frequency power supply 71 (4a) may be acquired in advance, and phase shifter 91 is installed in only one high-frequency power supply 4a (71), such that the phase of one high-frequency power supply 4a (71) with respect to the other high-frequency power supply 71 (4a) may be adjusted.

Further, the frequencies of the high frequencies supplied to gas shower head 4 and inductive coil 70 are not limited to 40 MHz as described above, and other frequencies, for example, 13.56 MHz or 100 MHz may be used in exemplary embodiments described below, and another frequency, for example 60 MHz may also be used. In addition, in each exemplary embodiment, the high frequencies supplied from first high-frequency power supply 4a and second high-frequency power supply 71 have the same phase (the phase difference: 0 degree) or the reverse phase (the phase difference: 180 degrees). However, phase shifter 91 may be adjusted in such a way that the phase difference becomes another phase difference, for example, 45 degrees.

In each exemplary embodiment, while inductive coil 70 (wires 111) is installed outside the inner space of processing container 21, outer top plate 60 (dielectric member 101) may be configured as a split structure (all not shown) of an upper part and a lower part, and for example, plural concave portions are formed at a regular interval in a circumferential direction of the lower part, such that inductive coil 70 (wires 111) may be received in the concave portions. Further, for example, inductive coil 70 (wires 111) may be installed in the inner space of processing container 21. In addition, at the time of forming electric field E2 in processing container 21, in addition to a single-phase coil, for example, a start-connected or triangle (Δ)-connected three-phase coil may be disposed in the circumferential direction of processing container 21.

In each exemplary embodiment, the etching processing has been exemplified as the plasma processing. The plasma processing apparatus of the present invention may be applied to, for example, a film formation processing apparatus using a chemical vapor deposition (CVD) method or an ashing processing apparatus by using the plasma. For example, in the film forming apparatus, the magnitudes of the high frequencies supplied from high-frequency power supplies 4a and 71 or the phase of the high-frequency wave adjusted by phase shifter 91 may be stored in the recipe according to processing conditions such as the type of film forming gas or the flow rate and pressure of gas, such that the film forming processing is performed at a uniform film forming speed in the plane.

### EXAMPLES

### Experimental Example 1

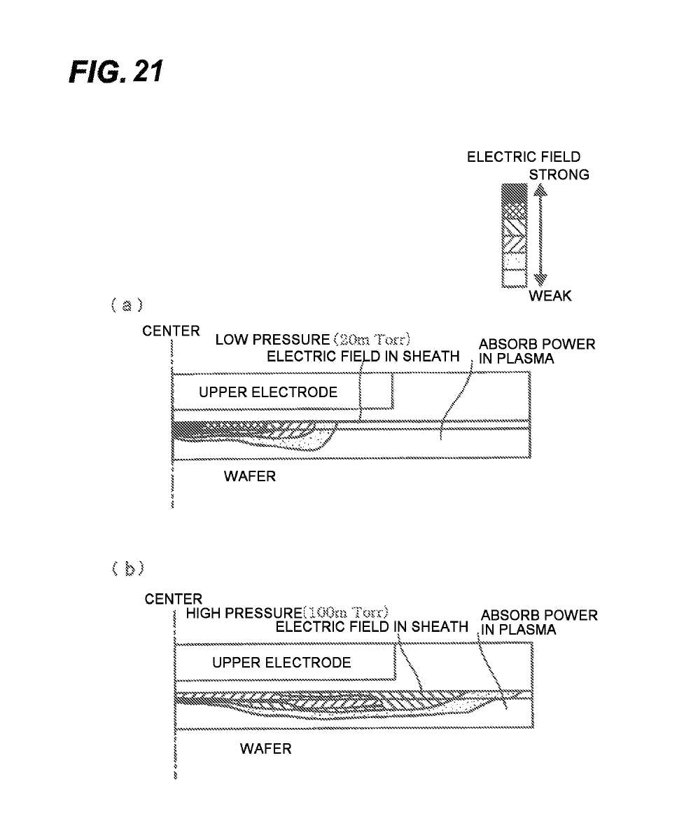

An experiment was performed for verifying how plasma (electrons) in a plane is distributed according to processing conditions at the time of making processing gas into plasma by supplying a high-frequency wave to a gas shower head 4 from a high-frequency power supply 4a, without supplying the high-frequency wave to inductive coil 70. The experiment was performed under the low pressure of 2.7 Pa (20 mTorr) and the high pressure of 13.3 Pa (100 mTorr), and the density of plasma at a circumferential margin from the center of an inner space of a processing container 21 was measured by using the Langmuir probe. In addition, FIG. 21A shows, for example, a result acquired with respect to a case in which the pressure in processing container 21 is low, and FIG. 21B shows, for example, a result acquired with respect to a case in which the pressure in processing container 21 is high. According to the results, when the pressure is low, gas shower head 4 and an opposite pole (a placing table 3) are electrically coupled with each other to become Stochastic heating, and as a result, it could be seen that the density of plasma at the center increases, whereas the density of plasma at the circumferential margin decreases. Meanwhile, when the pressure is high, gas shower head 4 and a side wall of processing container 21 are electrically coupled with each other to become an ohmic heating, and as a result, it could be seen that the density of plasma at the circumferential margin becomes higher than that at the center. Segregation of the densities of plasma at the center and the circumferential margin was caused by changes in various processing conditions as well as the pressure. Accordingly, as described above, in order to perform plasma etching processing uniformly in the plane, it could be seen that the density of plasma needs to be uniform for each processing condition.

### Experimental Example 2

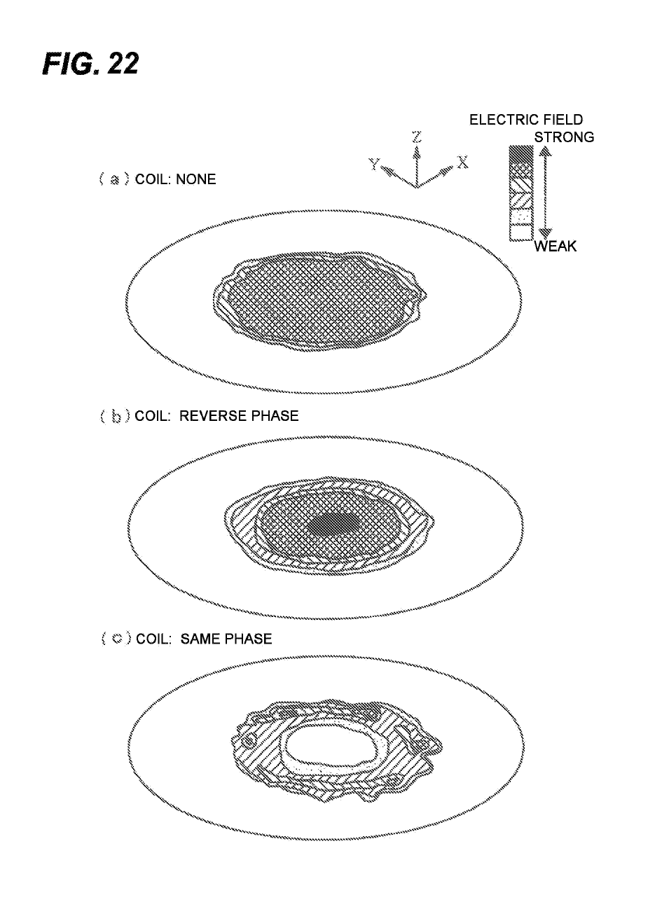

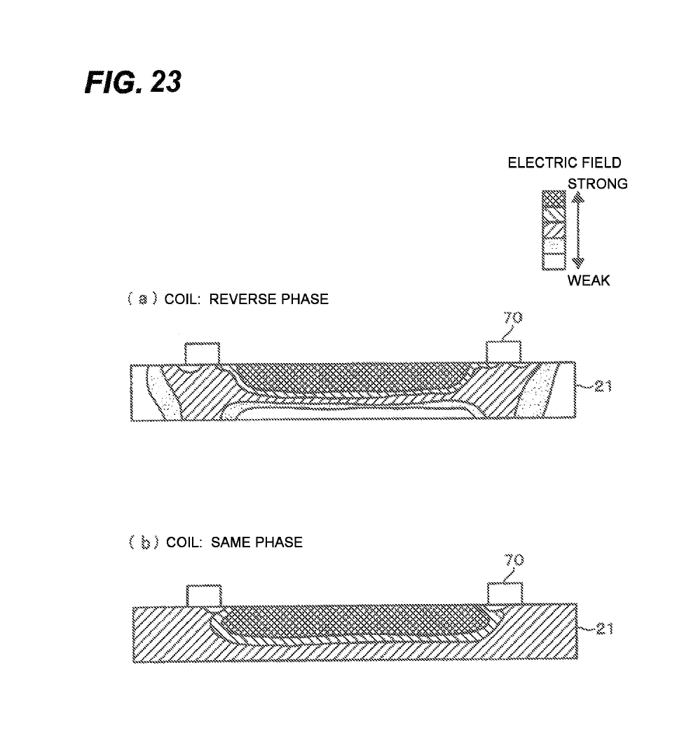

Following the results, an experiment was performed for verifying how the density of plasma is changed by supplying the high-frequency wave from high-frequency power supply 4a to gas shower head 4 and inductive coil 70. First, the processing condition (first high-frequency power supply 4a: 13.45 MHz, 50 V) was adjusted so that the concentration of plasma in processing container 21 becomes uniform without using inductive coil 70. In addition, in this processing condition, the high-frequency wave having a voltage of 20 V under the same frequency as first high-frequency power supply 4a (13.56 MHz) is supplied from second high-frequency power supply 71 to inductive coil 70 to measure how the distribution of plasma is changed. At this time, each phase of the high frequencies supplied to inductive coil 70 is adjusted so that the direction of an electric field E2 with respect to an electric field E1 has a reverse phase and the same phase, and thereafter, the cases were compared with a case (a comparison target) in which a high-frequency wave is not supplied to inductive coil 70. These results are shown in FIGS. 22 and 23.

FIG. 22A shows the density of plasma of the comparison target, FIGS. 22B and 23A show the density distribution of plasma when the phase of the high-frequency wave is adjusted so that electric field E2 has a phase reverse to electric field E1, and FIGS. 22C and 23B show the density distribution of plasma when the phase of the high-frequency wave is adjusted so that electric field E1 and electric field E2 have the same phase as each other. As a result, by forming electric field E2 having the reverse phase to electric field E1, plasma is pushed into the center, that is, electric field E1 is confined to the center. Meanwhile, plasma is spread to the circumferential margin by forming electric field E2 having the same phase as electric field E1, but it could be seen that plasma absorbed in the side wall of processing container 21 is rarely seen, and as a result, energy of plasma is rarely lost. Accordingly, by adjusting the phase of the high-frequency wave supplied to inductive coil 70 so that electric field E1 and electric field E2 have the same phase or the reverse phase, the density of plasma could be adjusted so that the concentration of plasma becomes uniform in the plane.

### Experimental Example 3

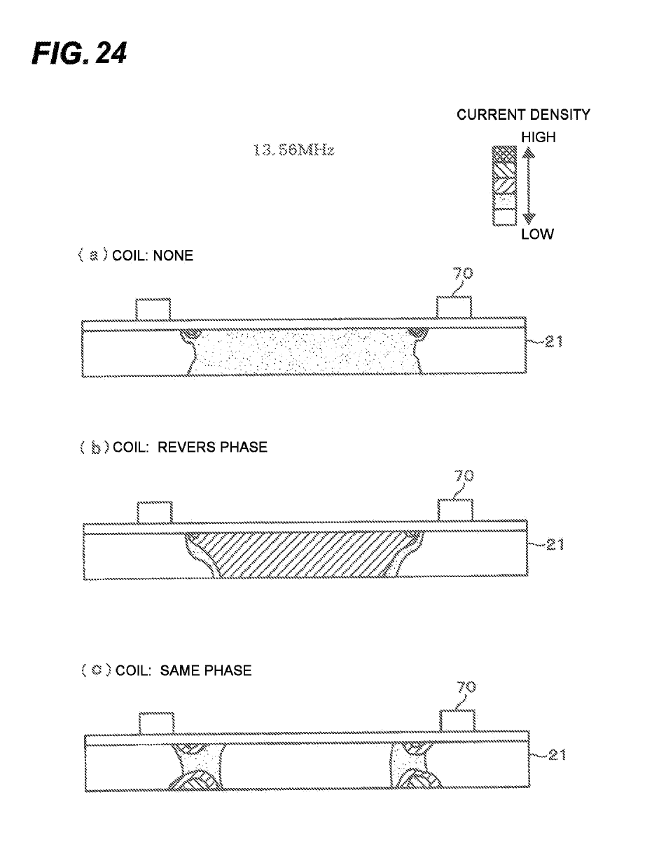

Next, in regards to each example of experimental example 2, the total current density in processing container 21 was calculated using a numerical simulation. This result is shown in FIG. 24. According to the result, electric field E2 has the reverse phase to electric field E1, such that plasma is pushed into the center, whereas electric field E1 and electric field E2 have the same phase, such that plasma was attracted to the circumferential margin.

### Experimental Example 4

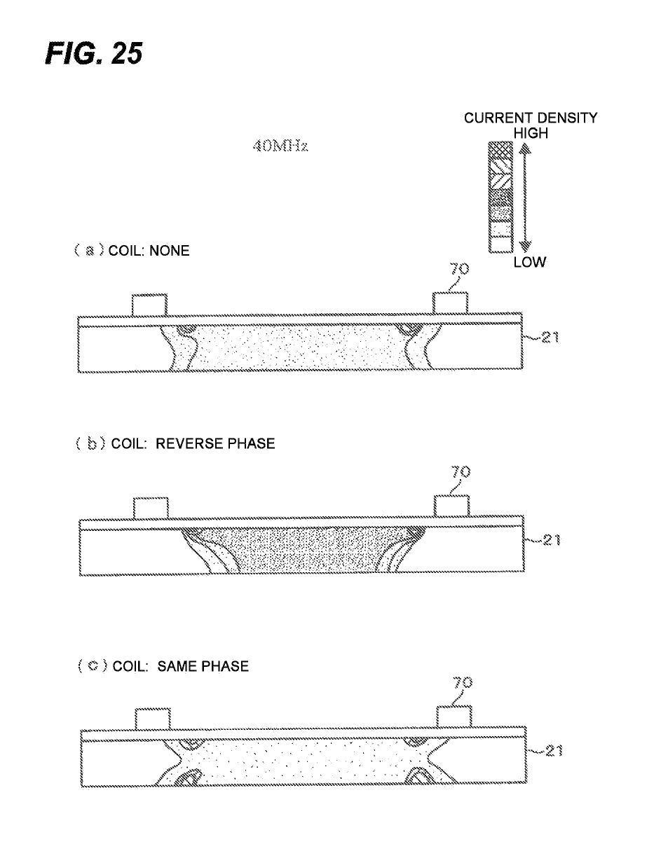

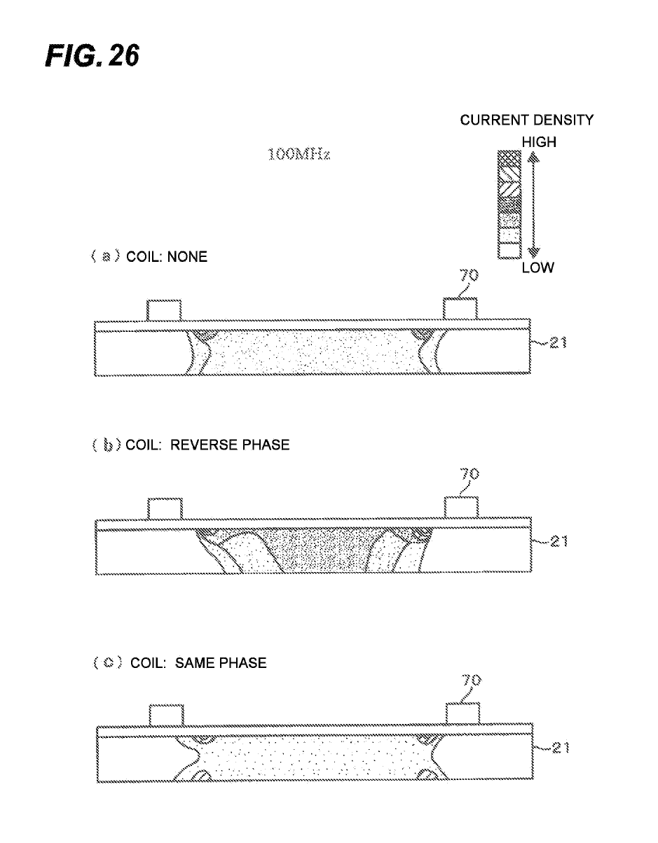

A result is shown acquired by changing the frequencies of the high frequencies supplied to gas shower head 4 and inductive coil 70 to 40 MHz (FIG. 25) and 100 MHz (FIG. 26) by using the same numerical simulation as experimental example 3 described above. As a result, it could be seen that the same result can be acquired regardless of the frequencies of the high frequencies supplied to gas shower head 4 and inductive coil 70.

1. A plasma processing apparatus including a processing container, a placing table which is a lower electrode installed in the processing container, and a gas shower head which is an upper electrode and forms a supplying unit of a processing gas, where the plasma processing apparatus makes the processing gas into plasma by applying a high-frequency electric power for generating plasma between the lower electrode and the upper electrode, and performs a plasma processing of a substrate disposed on the placing table by using plasma, the apparatus is characterized by comprising:
a first high-frequency power supply connected to any one of the upper electrode and the lower electrode configured to output the high-frequency electric power for generating plasma;
a second high-frequency power supply configured to output a high-frequency electric power having the same output frequency as the first high-frequency power supply;
an inductive coil disposed to surround the one electrode connected to the first high-frequency power supply when viewed from the top side and configured to form a horizontal-direction electric field along a line connecting a side wall of the processing container and an upper region of a center of the substrate in the processing container by the high-frequency electric power supplied from the second high-frequency power supply; and
a phase difference adjusting means configured to adjust a phase difference between high frequencies outputted from the first high-frequency power supply and the second high-frequency power supply in order to adjust strength of a combined electric field of a horizontal-direction generated around the one electrode in the processing container by supplying the high-frequency electric power from the first high-frequency power supply and the horizontal-direction electric field formed by the inductive coil.

2. The plasma processing apparatus of claim 1, wherein an adjusting operation of adjusting the strength of the combined electric field is an operation that sets phases of the horizontal-direction electric field formed by the first high-frequency power supply and the horizontal-direction electric field formed by the second high-frequency power supply to the same phase or a reverse phase.

3. The plasma processing apparatus of claim 1, wherein a plurality of inductive coils are disposed in a circumferential direction of the processing container and lengths of each conductive passage connecting each of the plurality of inductive coils and the second high-frequency power supply have the same length.

4. The plasma processing apparatus of claim 1, further comprising a negative voltage supplying means connected to the gas shower head configured to push the electric field inducted by the inductive coil to the center of the processing container.

5. The plasma processing apparatus of claim 1, wherein the phase difference adjusting means includes a control unit configured to output a control signal for adjusting the phase difference between the horizontal-direction electric field formed by the first high-frequency power supply and the horizontal-direction electric field formed by the second high-frequency power supply.

6. The plasma processing apparatus of claim 5, wherein the control unit has a function to selectively output a control signal for adjusting the phases of the horizontal-direction electric field formed by the first high-frequency power supply and the horizontal-direction electric field formed by the second high-frequency power supply to the same phase, and a control signal for adjusting the corresponding horizontal-direction electric fields to reverse phases.

7. The plasma processing apparatus of claim 5, further comprising a storage unit correlatively storing a processing recipe performed with respect to the substrate and an adjustment amount of the phase by the phase difference adjusting means, wherein the control unit reads the adjustment amount depending on the recipe from the storage unit and outputs a control signal.
